(19) United States
(12) Patent Application Publication
(10) Pub. No.: US 2021/0036134 A1
(43) Pub. Date: Feb. 4, 2021

(54) Bipolar Transistor and Production Method Therefor

(71) Applicant: Nippon Telegraph and Telephone Corporation, Tokyo (JP)

(72) Inventors: Yuta Shiratori, Tokyo (JP); Minoru Ida, Tokyo (JP)

(21) Appl. No.: 17/046,236

(22) PCT Filed: Apr. 15, 2019
(86) PCT No.: PCT/JP2019/016117

§ 371 Date: Oct. 8, 2020

(30) Foreign Application Priority Data
Apr. 24, 2018 (JP) 2018-082781

(51) Int. Cl. H01L 29/737; H01L 29/417; H01L 29/423; H01L 23/373; H01L 23/367; H01L 29/66

(52) U.S. Cl. CPC H01L 29/737; H01L 29/41708; H01L 29/66318; H01L 23/373; H01L 23/367; H01L 29/42304

(57) ABSTRACT

An element portion is formed on a heat dissipation substrate, and the element portion includes a collector layer, a base layer, an emitter layer, an emitter cap layer, an emitter electrode, and a base electrode. A metallic emitter heat dissipation via that connects an emitter wiring to an emitter heat dissipation pad is provided, and a metallic base heat dissipation via that connects a base wiring to a base heat dissipation pad is also provided.

### CROSS-REFERENCE TO RELATED APPLICATIONS

This application is a national phase entry of PCT Application No. PCT/JP2019/016117, filed on Apr. 15, 2019, which claims priority to Japanese Application No. 2018-082781, filed on Apr. 24, 2018, which applications are hereby incorporated herein by reference.

### TECHNICAL FIELD

The present invention relates to a bipolar transistor that includes a heterojunction, and a manufacturing method for the same.

### BACKGROUND

An indium phosphate (InP) double heterojunction bipolar transistor (DHBT) is a transistor that is excellent in terms of speed and output due to the high electron speed and the high breakdown field strength of the InP material, and is applied mainly in integrated circuits for optical communication. In order to further increase the speed and output of an InP-based DHBT while also maintaining the reliability of the DHBT, it is essential to lower the junction temperature through an improvement in heat dissipation. A structure in which an InP-based DHBT is formed on a heat dissipation substrate made of a material that has a high thermal conductivity, such as silicon (Si), has been proposed and is under technical review (NPL 1) as a technique for achieving the aforementioned goals.

The following describes the configuration of an InP-based DHBT that is formed on a heat dissipation substrate 301 made of Si, with reference to FIG. 3. This DHBT includes a metallic sub-collector layer 302 that is formed on the heat dissipation substrate 301, a collector layer 303 that is made of a compound semiconductor doped with an n-type impurity at a low concentration, a base layer 304 that is made of a compound semiconductor doped with a p-type impurity at a high concentration, an emitter layer 305 made of a compound semiconductor doped with an n-type impurity at a low concentration, and an emitter cap layer 306 made of a compound semiconductor doped with an n-type impurity at a high concentration.

A metallic emitter electrode 307 is formed on and connected to the emitter layer 305, and a metallic base electrode 308 is formed on and connected to the base layer 304. The element portion is then covered by an insulation film 309 made of a resin. Note that the metallic sub-collector layer 302 is an adhesion layer used when the compound semiconductor crystalline layers, from the emitter cap layer 306 to the collector layer 303, are mechanically joined to the heat dissipation substrate 301, and also functions as a collector electrode.

In general, in a DHBT, heat is generated in the collector layer and dissipated to the lower surface of the substrate (the surface on which the DHBT is not formed). This is because when a DHBT integrated circuit is mounted to and housed in a package, it is common for the lower surface of the substrate provided with the integrated circuit to be directly bonded to the package. Accordingly, the portion directly below the collector layer in the DHBT is constituted by the metallic sub-collector layer and the heat dissipation substrate made of Si, which have a higher thermal conductivity than the InP-based material, and thus the heat dissipation is higher than in the case where the DHBT is formed on an InP substrate.

### CITATION LIST

### Non Patent Literature

NPL 1—A. Thiam et al., “InP HBT Thermal Management by Transferring to High Thermal Conductivity Silicon Substrate”, IEEE Electron Device Letters, vol. 35, issue 10, pp. 1010-1012, 2014.
NPL 2—D. W. Scott et al., “InP HBT Transferred to Higher Thermal Conductivity Substrate”, IEEE Electron Device Letters, vol. 33, no. 4, pp. 507-509, 2012.

### SUMMARY

### Technical Problem

However, in the conventional DHBT structure described above, it is not easy to further improve the dissipation of heat from the collector layer to the lower surface of the substrate without a tradeoff with electrical characteristics. More specifically, when examining methods for improving heat dissipation along the aforementioned path, a conceivable first method is to form the heat dissipation substrate from a material that has a higher thermal conductivity, and also reduce the thickness of the heat dissipation substrate. A conceivable second method is to form the metallic sub-collector layer from a material that has a higher thermal conductivity, and also reduce the thickness of the metallic sub-collector layer. A conceivable third method is to form the collector layer from a material that has a higher thermal conductivity, and also reduce the thickness of the collector layer.

With the first method, it is sufficient to use a substrate made from silicon carbide (SiC) or aluminum nitrate (AlN), which have a higher thermal conductivity than Si, and it has been reported that there is an improvement in heat dissipation when an InP-based DHBT is actually formed on an SiC substrate (see NPL 2). When improving heat dissipation by reducing the thickness of the substrate, a significant effect of improving heat dissipation can be obtained only if the thickness of the substrate is reduced to approximately 1 μm, but this results in a large loss in mechanical strength, thus leading to concerns of a reduction in yield.

With the second method, NPL 1 has already proposed the use of Au, which has a high thermal conductivity even among metals, and it is difficult to achieve a large improvement in heat dissipation. Also, a reduction in the thickness of the metallic sub-collector layer invites an increase in collector parasitic resistance, thus leading to concerns of a reduction in high frequency characteristics. The third method has a large influence on overall electrical characteristics such as withstand voltage and high frequency characteristics, and such a change is not easy.

In light of the above, with current technology, it is difficult to improve the heat dissipation of an InP-based DHBT without a reduction in electrical characteristics and mechanical strength.

Embodiments of the present invention were achieved in order to solve the foregoing issues, and an object of the present invention is to further improve the heat dissipation of an InP-based DHBT without a reduction in electrical characteristics and mechanical strength.

### Means for Solving the Problem

A bipolar transistor according to embodiments of the present invention includes: a heat dissipation substrate that is insulating and has a higher thermal conductivity than InP; a collector heat dissipation pad, an emitter heat dissipation pad, and a base heat dissipation pad that are made of a metal, are in contact with an upper surface of the heat dissipation substrate, and are insulated and separated from each other; a collector layer that is made of a compound semiconductor and is formed on the collector heat dissipation pad; a base layer that is made of a compound semiconductor and is formed on the collector layer; an emitter layer that is made of a different compound semiconductor from the base layer and is in contact with an upper surface of the base layer; an emitter cap layer that is made of a compound semiconductor and is formed on the emitter layer; an emitter electrode formed on the emitter cap layer; a base electrode that is formed on the base layer around the emitter layer; an emitter wiring that is made of a metal, is formed in a wiring formation layer above the emitter cap layer, and is electrically connected to the emitter electrode; a base wiring that is made of a metal, is formed in the wiring formation layer, and is electrically connected to the base electrode; an emitter heat dissipation via that is made of a metal and connects the emitter wiring to the emitter heat dissipation pad; and a base heat dissipation via that is made of a metal and connects the base wiring to the base heat dissipation pad.

The bipolar transistor may further include: a collector wiring that is made of a metal, is formed in the wiring formation layer, and is electrically connected to the collector heat dissipation pad; and a collector post electrode that is made of a metal and connects the collector wiring to the collector heat dissipation pad.

The bipolar transistor may further include: an emitter post electrode that is made of a metal and connects the emitter wiring to the emitter electrode; and a base post electrode that is made of a metal and connects the base wiring to the base electrode.

The bipolar transistor may further include: an insulation film formed on the heat dissipation substrate so as to cover an element portion that includes the collector layer, the base layer, the emitter layer, the emitter cap layer, the emitter electrode, and the base electrode, and also cover the collector heat dissipation pad, the emitter heat dissipation pad, and the base heat dissipation pad, wherein the emitter heat dissipation via may pass through the insulation film over the emitter electrode, and the base heat dissipation via may pass through the insulation film over the base electrode.

A manufacturing method for a bipolar transistor according to embodiments of the present invention includes: a first step of forming a metal layer on a heat dissipation substrate that is insulating and has a higher thermal conductivity than InP; a second step of forming an element portion on the metal layer, the element portion including a collector layer made of a compound semiconductor, a base layer that is made of a compound semiconductor and is formed on the collector layer, an emitter layer that is made of a different compound semiconductor from the base layer and is in contact with an upper surface of the base layer, an emitter cap layer that is made of a compound semiconductor and is formed on the emitter layer, an emitter electrode formed on the emitter cap layer, and a base electrode that is formed on the base layer around the emitter layer; a third step of forming a collector heat dissipation pad, an emitter heat dissipation pad, and a base heat dissipation pad that are in contact with an upper surface of the heat dissipation substrate and are insulated and separated from each other, by performing patterning on the metal layer; a fourth step of forming, all at once, an emitter heat dissipation via that is made of a metal and is arranged in contact with an upper surface of the emitter heat dissipation pad, a base heat dissipation via that is made of a metal and is arranged in contact with an upper surface of the base heat dissipation pad, a collector post electrode that is made of a metal and is arranged in contact with an upper surface of the collector heat dissipation pad, an emitter post electrode that is made of a metal and is arranged in contact with an upper surface of the emitter electrode, and a base post electrode that is made of a metal and is arranged in contact with an upper surface of the base electrode; a fifth step of forming an insulation film on the heat dissipation substrate, the insulation film covering the element portion, the collector heat dissipation pad, the emitter heat dissipation pad, the base heat dissipation pad, the emitter heat dissipation via, the base heat dissipation via, the collector post electrode, the emitter post electrode, and the base post electrode; and a sixth step of forming, all at once in a wiring formation layer on the insulation film, an emitter wiring that is made of a metal and is connected to the emitter post electrode and the emitter heat dissipation via, a base wiring that is made of a metal and is connected to the base post electrode and the base heat dissipation via, and a collector wiring that is connected to the collector post electrode.

### Effects of Embodiments of the Invention

As described above, according to embodiments of the present invention, the metallic emitter heat dissipation via that connects the emitter wiring to the emitter heat dissipation pad is provided on the heat dissipation substrate, and the metallic base heat dissipation via that connects the base wiring to the base heat dissipation pad is also provided on the heat dissipation substrate, thus obtaining an excellent effect of making it possible to further improve the heat dissipation of an InP-based DHBT without a reduction in electrical characteristics and mechanical strength.

### BRIEF DESCRIPTION OF THE DRAWINGS

FIG. 1A is a cross-sectional view of a configuration of a bipolar transistor according to an embodiment of the present invention.

FIG. 1B is a cross-sectional view of a configuration of a bipolar transistor according to an embodiment of the present invention.

FIG. 1C is a plan view of a configuration of a bipolar transistor according to an embodiment of the present invention.

FIG. 2A is a cross-sectional view of states in steps for illustrating a manufacturing method for a bipolar transistor according to an embodiment of the present invention.

FIG. 2B is a cross-sectional view of states in steps for illustrating a manufacturing method for a bipolar transistor according to an embodiment of the present invention.

FIG. 2C is a cross-sectional view of states in steps for illustrating a manufacturing method for a bipolar transistor according to an embodiment of the present invention.

FIG. 2D is a cross-sectional view of states in steps for illustrating a manufacturing method for a bipolar transistor according to an embodiment of the present invention.

FIG. 2E is a cross-sectional view of states in steps for illustrating a manufacturing method for a bipolar transistor according to an embodiment of the present invention.

FIG. 2F is a plan view of states in steps for illustrating a manufacturing method for a bipolar transistor according to an embodiment of the present invention.

FIG. 2G is a cross-sectional view of states in steps for illustrating a manufacturing method for a bipolar transistor according to an embodiment of the present invention.

FIG. 2H is a cross-sectional view of states in steps for illustrating a manufacturing method for a bipolar transistor according to an embodiment of the present invention.

FIG. 2I is a plan view of states in steps for illustrating a manufacturing method for a bipolar transistor according to an embodiment of the present invention.

FIG. 2J is a plan view of states in steps for illustrating a manufacturing method for a bipolar transistor according to an embodiment of the present invention.

FIG. 2K is a cross-sectional view of states in steps for illustrating a manufacturing method for a bipolar transistor according to an embodiment of the present invention.

FIG. 2L is a cross-sectional view of states in steps for illustrating a manufacturing method for a bipolar transistor according to an embodiment of the present invention.

FIG. 2M is a cross-sectional view of states in steps for illustrating a manufacturing method for a bipolar transistor according to an embodiment of the present invention.

FIG. 2N is a cross-sectional view of states in steps for illustrating a manufacturing method for a bipolar transistor according to an embodiment of the present invention.

FIG. 3 is a cross-sectional view of a configuration of a heterojunction bipolar transistor.

### DETAILED DESCRIPTION OF ILLUSTRATIVE EMBODIMENTS

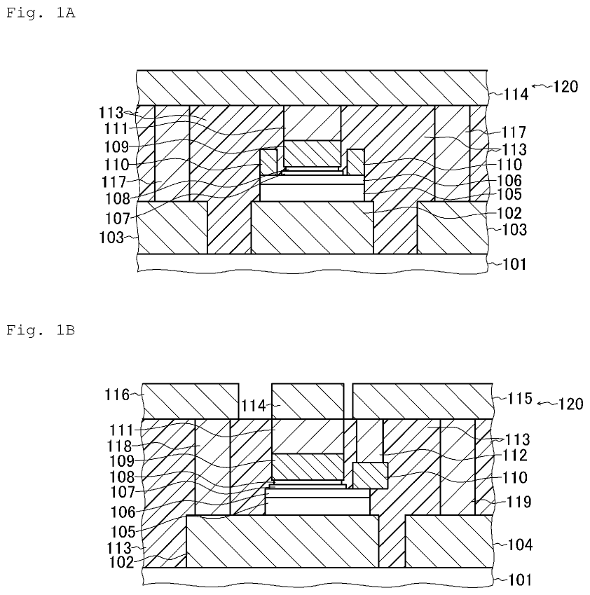

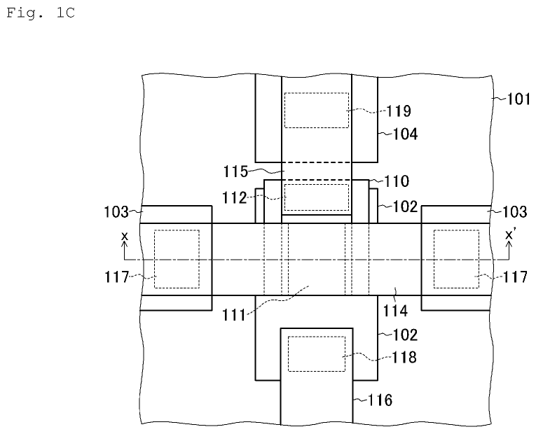

Hereinafter, a bipolar transistor according to an embodiment of the present invention is described with reference to FIGS. 1A, 1B, and 1C. This bipolar transistor is a double heterojunction bipolar transistor (DHBT).

First, the DHBT includes a heat dissipation substrate 101 that is insulating and has a higher thermal conductivity than InP, and a collector heat dissipation pad 102, emitter heat dissipation pads 103, and a base heat dissipation pad 104, which are made of a metal, are in contact with the upper surface of the heat dissipation substrate 101, and are insulated and separated from each other. Also, a commonly known DHBT element portion is formed on the collector heat dissipation pad 102, and the DHBT element portion includes a collector layer 105, a base layer 106, an emitter layer 107, an emitter cap layer 108, an emitter electrode 109, and a base electrode 110. In the element portion, as commonly known, the emitter layer 107 (the emitter cap layer 108) has a rectangular shape in a plan view, that is to say, one of the two sets of parallel sides is longer than the other than.

The emitter electrode 109 is formed on the emitter cap layer 108, and the base electrode 110 is formed on the base layer 106 around the emitter layer 107. Note that although the base electrode 110 is approximately shaped as a “U” that partially surrounds the emitter layer 107 in a plan view in the present embodiment, the base electrode 110 may be formed so as to completely surround the emitter layer 107. Here, FIG. 1A shows a cross-section along a line xx′ in the plan view in FIG. 1C. Also, FIG. 1B shows a cross-section along a plane that is perpendicular to the plane of the heat dissipation substrate 101 and is also perpendicular to the cross-section in FIG. 1A. FIG. 1B is a longitudinal cross-section of the emitter layer 107 that is rectangular in a plan view.

The heat dissipation substrate 101 is made of SiC, for example. The collector layer 105 is made of n-InP, which is a compound semiconductor that has been doped with Si at a low concentration for example, the base layer 106 is made of p+-GaAsSb, which is a compound semiconductor that has been doped with C at a high concentration for example, and the emitter layer 107 is made of n-InP, which is a compound semiconductor that has been doped with Si at a low concentration for example. Also, the emitter cap layer 108 is made of n+-InGaAs, which is a compound semiconductor that has been doped with Si at a high concentration. The emitter layer 107 is made of a different compound semiconductor from the base layer 106.

The DHBT further includes a metallic emitter wiring 114 that is formed in a wiring formation layer 120 above the emitter cap layer 108 and is electrically connected to the emitter electrode 109, and a metallic base wiring 115 that is formed in the wiring formation layer 120 and is electrically connected to the base electrode 110.

The DHBT further includes metallic emitter heat dissipation vias 117 that connect the emitter wiring 114 to the emitter heat dissipation pads 103, and a metallic base heat dissipation via 119 that connects the base wiring 115 to the base heat dissipation pad 104.

The DHBT further includes a metallic collector wiring 116 that is formed in the wiring formation layer 120 and is electrically connected to the collector heat dissipation pad 102, a metallic collector post electrode 118 that connects the collector wiring 116 to the collector heat dissipation pad 102, a metallic emitter post electrode 11 that connects the emitter wiring 114 to the emitter electrode 109, and a metallic base post electrode 112 that connects the base wiring 115 to the base electrode 110.

The DHBT further includes an insulation film 113 that is formed on the heat dissipation substrate 101 so as to cover the element portion, which includes the collector layer 105, the base layer 106, the emitter layer 107, the emitter cap layer 108, the emitter electrode 109, and the base electrode 110, and so as to also cover the collector heat dissipation pad 102, the emitter heat dissipation pads 103, and the base heat dissipation pad 104. The emitter heat dissipation vias 117 pass through the insulation film 113 over the emitter electrode 109, and the base heat dissipation via 119 passes through the insulation film 113 over the base electrode 110.

In the above-described DHBT according to the present embodiment, heat generated in the element portion, which is constituted by compound semiconductors, is dissipated along three routes described below.

Route A: from the emitter electrode 109 to the lower surface of the heat dissipation substrate 101 via the emitter wiring 114, the emitter heat dissipation vias 117, and the emitter heat dissipation pads 103.

Route B: from the base electrode 110 to the lower surface of the heat dissipation substrate 101 via the base wiring 115, the base heat dissipation via 119, and the base heat dissipation pad 104.

Route C: from the collector heat dissipation pad 102 to the lower surface of the heat dissipation substrate 101.

For this reason, according to the DHBT of the present embodiment, the heat dissipation can be improved over the conventional structure in which heat is dissipated only via the route C. As will be described later, in the DHBT according to the present embodiment, a metallic adhesion layer is used when the compound semiconductor layers from the emitter cap layer 108 to the collector layer 105 are joined to the heat dissipation substrate 101, and that metallic adhesion layer is patterned and used as the emitter heat dissipation pads 103, the base heat dissipation pad 104, and the collector heat dissipation pad 102. Also, with the DHBT, the emitter heat dissipation vias 117 and the base heat dissipation via 119 are formed along with the step for forming the post electrodes that are provided in order to connect the emitter electrode 109, the base electrode 110, and the collector electrode (collector heat dissipation pad 102) to the corresponding wiring. For this reason, the heat dissipation can be improved without any additional steps.

As described above, according to the DHBT of the present embodiment, it is possible to easily improve the heat dissipation without a reduction in electrical characteristics and mechanical strength, and without additional steps.

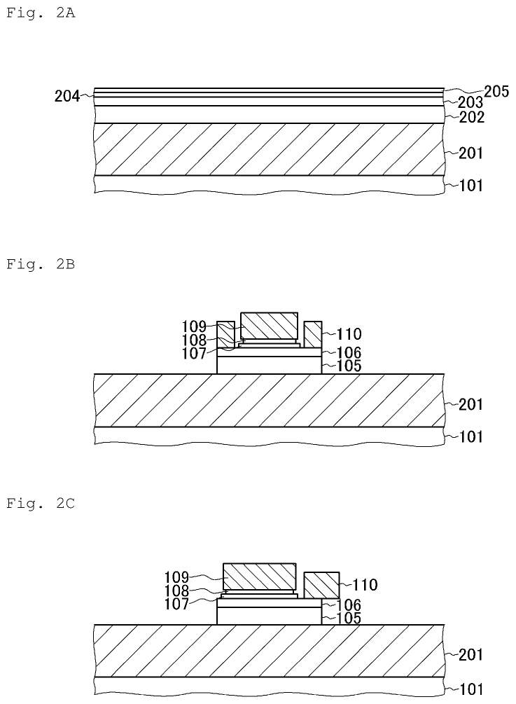

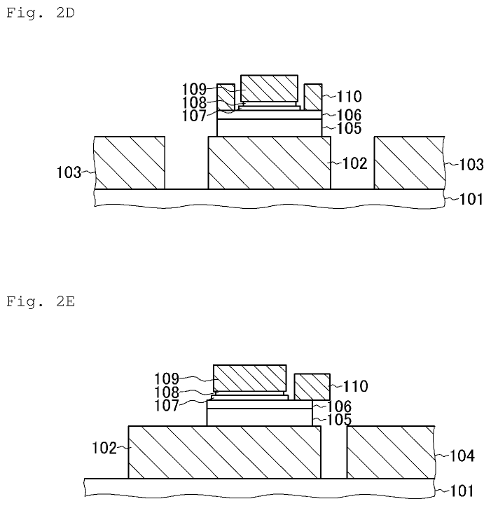

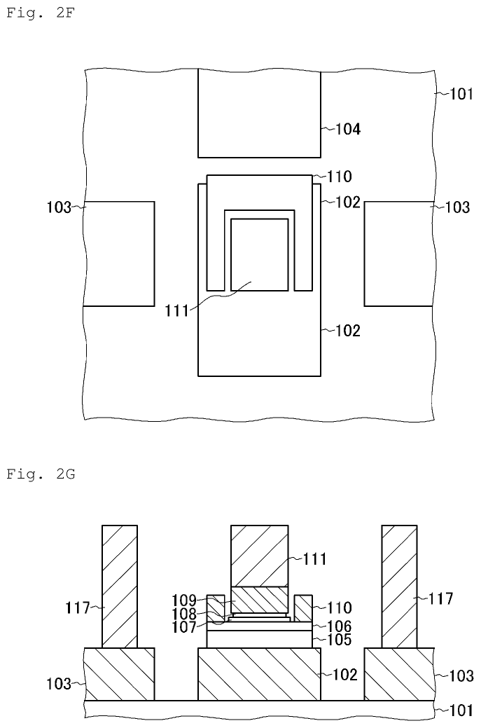

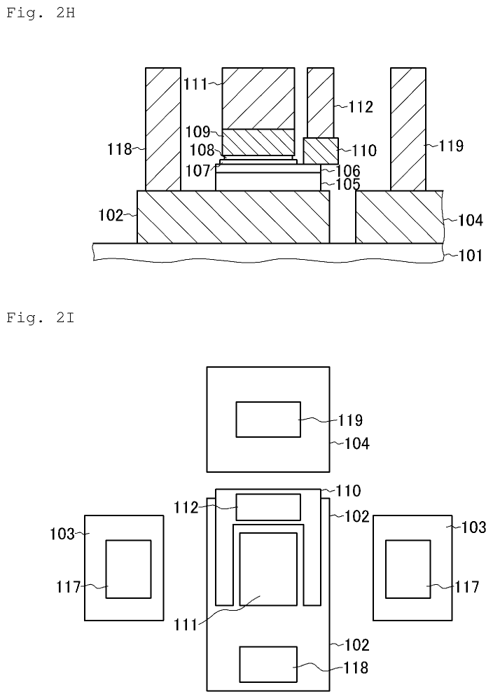

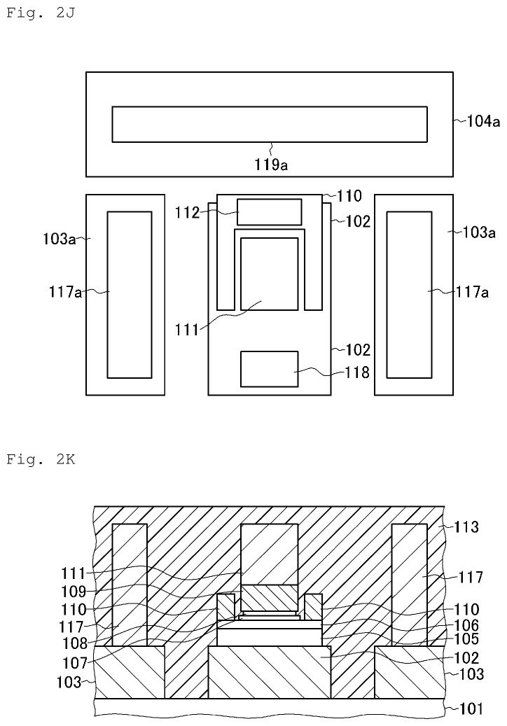

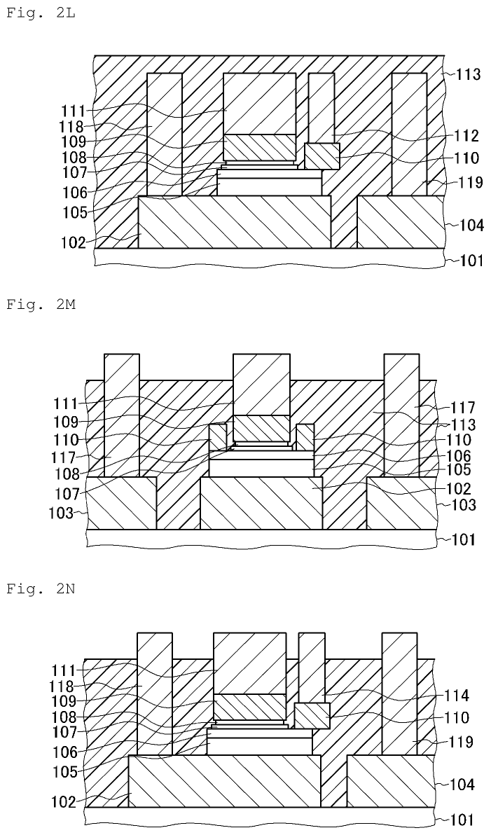

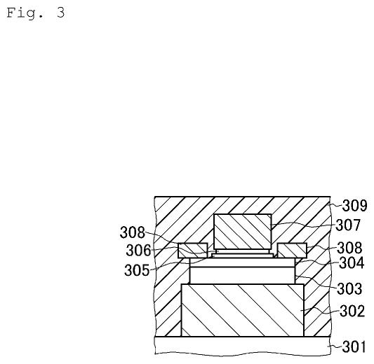

Next, a manufacturing method for a bipolar transistor according to an embodiment of the present invention will be described with reference to FIGS. 2A to 2N.

First, as shown in FIG. 2A, a metal layer 201 is formed on the heat dissipation substrate 101 (first step). The heat dissipation substrate 101 is made of SiC, which is insulating and has a higher thermal conductivity than InP. The metal layer 201 may be made of Au, for example.

Next, in the DHBT, four layers are formed on the metal layer 201, namely a collector formation layer 202 made of n-InP doped with Si at a low concentration, a base formation layer 203 made of p+-GaAsSb doped with C at a high concentration, an emitter formation layer 204 made of n-InP doped with Si at a low concentration, and an emitter cap formation layer 205 made of n+-InGaAs doped with Si at a high concentration.

For example, commonly known organometallic vapor phase growing, molecular beam epitaxy, or the like is used to form sacrificing layers on a growth substrate made of InP, and then the above-described compound semiconductor layers are formed by epitaxial growth. Here, the top layer becomes the collector formation layer 202. Next, an adhesive metal layer made of Au is formed on the collector formation layer 202. The adhesive metal layer made of Au is also formed on the heat dissipation substrate 101.

Next, the growth substrate and the heat dissipation substrate 101 are affixed together by joining the adhesive metal layers to each other using a known wafer joining technique. Au has a low Young's modulus and very high oxidation resistance, and has a thermal conductivity of 320 W/m/K, which is high even among metals. Accordingly, this configuration is favorable in terms of joining, and is also favorable in terms of obtaining the heat dissipation pads, as will be described later.

Through the affixing described above, the two adhesive metal layers are joined together to form the metal layer 201, and the above-described compound semiconductor layers are formed on the metal layer 201. Thereafter, the growth substrate is eliminated with use of the sacrificing layers, thus obtaining a state in which the metal layer 201, the collector formation layer 202, the base formation layer 203, the emitter formation layer 204, and the emitter cap formation layer 205 are formed on the heat dissipation substrate 101.

Next, the emitter cap formation layer 205, the emitter formation layer 204, the base formation layer 203, and the collector formation layer 202 are patterned using a known photolithography technique or etching technique, and thus the element portion, which includes the collector layer 105, the base layer 106, the emitter layer 107, and the emitter cap layer 108, is formed on the metal layer 201 as shown in FIGS. 2B and 2C. Then the emitter electrode 109 and the base electrode 110 are formed (second step). Note that FIG. 2B is a cross-sectional view along line xx′ in the plan view of FIG. 1C. Also, FIG. 2C shows a cross-section along a plane that is perpendicular to the plane of the heat dissipation substrate 101 and is also perpendicular to the cross-section in FIG. 2B. FIG. 2C is a longitudinal cross-section of the emitter layer 107 that is rectangular in a plan view.

Next, the metal layer 201 is patterned using a known photolithography technique or etching technique, thus forming the collector heat dissipation pad 102, the emitter heat dissipation pads 103, and the base heat dissipation pad 104 that are in contact with the upper surface of the heat dissipation substrate 101 and are insulated and separated from each other as shown in FIGS. 2D, 2E, and 2F (third step). For example, a mask pattern that includes pattern portions corresponding to the respective portions is formed using photolithography. Next, it is sufficient that, using the formed mask pattern as a mask, the metal layer 201, which is made of Au, is etched through wet etching performed using an iodine-based wet etchant. Etching may also be performed through Ar milling. Note that FIG. 2D shows a cross-section taken at the same plane as in FIG. 2B, and FIG. 2E shows a cross-section taken at the same plane as in FIG. 2C. Also, FIG. 2F is a plan view.

Next, as shown in FIGS. 2G, 2H, and 2I, the emitter heat dissipation vias 117, the base heat dissipation via 119, the collector post electrode 118, the emitter post electrode 11, and the base post electrode 112 are formed all at once (fourth step). FIG. 2G shows a cross-section taken at the same plane as in FIG. 2B, and FIG. 2H shows a cross-section taken at the same plane as in FIG. 2C. Also, FIG. 2I is a plan view. The heat dissipation substrate 101 is not shown in FIG. 2I.

Note that the emitter heat dissipation vias 117 are arranged in contact with the upper surface of the emitter heat dissipation pads 103. The base heat dissipation via 119 is arranged in contact with the upper surface of the base heat dissipation pad 104. The collector post electrode 118 is arranged in contact with the upper surface of the collector heat dissipation pad 102. The emitter post electrode 11 is arranged in contact with the upper surface of the emitter electrode 109. The base post electrode 112 is arranged in contact with the upper surface of the base electrode 110.

It is sufficient that the above-described post electrodes are formed using a known lithography technique, vacuum deposition technique, or lift-off technique, for example.

As another design for the heat dissipation vias and heat dissipation pads in order to raise the heat dissipation effect in the DHBT in the present embodiment, first, emitter heat dissipation vias 117a and emitter heat dissipation pads 103a have an increased length and width within the allowable range of the DHBT cell size in terms of circuit design, as shown in FIG. 2J. Second, a base heat dissipation via 119a and a base heat dissipation pad 104a have an increased length and width. As long as at least the lengths and widths are approximately 1 μm, a sufficient effect is obtained. FIG. 2J is a plan view. The heat dissipation substrate 101 is not shown in FIG. 2J.

Additionally, setting the heights of the post electrodes and the heat dissipation vias as low as possible results in a shorter heat dissipation path, thus making it possible to improve heat dissipation. However, the height of the post electrodes and the heat dissipation vias needs to be at least higher than the thickness of the element portion (the thickness from the emitter electrode 109 to the collector layer 105).

Next, as shown in FIGS. 2K and 2L, the insulation film 113, which covers the element portion, the collector heat dissipation pad 102, the emitter heat dissipation pads 103, the base heat dissipation pad 104, the emitter heat dissipation vias 117, the base heat dissipation via 119, the collector post electrode 118, the emitter post electrode 11, and the base post electrode 112, is formed on the heat dissipation substrate 101 (fifth step). The insulation film 113 is formed so as to have a flat upper surface. For example, the insulation film 113 can be formed by forming a resin film through performing spin coating with a resin such as benzo cyclobutene (BCB), and then heating the resin film so as to become thermoset. Note that FIG. 2K shows a cross-section taken at the same plane as in FIG. 2B, and FIG. 2L shows a cross-section taken at the same plane as in FIG. 2C.

Next, the insulation film 113 is etched back so as to expose the upper portions of the post electrodes and the heat dissipation vias, as shown in FIGS. 2M and 2N. If the insulation film 113 is made of BCB, it is sufficient that etch back is performed through dry etching performed using fluorine gas.

Next, the metallic emitter wiring 114 connected to the emitter post electrode 11 and the emitter heat dissipation vias 117, the metallic base wiring 115 connected to the base post electrode 112 and the base heat dissipation via 119, and the collector wiring 116 connected to the collector post electrode 118 are formed all at once in the wiring formation layer 120 on the insulation film 113 through a known semiconductor process (sixth step). The above-described manufacturing method obtains the DHBT according to the embodiment that was described using FIGS. 1A, 1B, and 1C.

As described above, according to embodiments of the present invention, a metallic emitter heat dissipation via that connects the emitter wiring to the emitter heat dissipation pad is provided on the heat dissipation substrate, and a metallic base heat dissipation via that connects the base wiring to the base heat dissipation pad is also provided on the heat dissipation substrate, thus making it possible to further improve the heat dissipation of the InP-based DHBT without a reduction in electrical characteristics and mechanical strength.

Note that the present invention is not limited to the embodiments described above, and it is obvious that a person having a general knowledge in the applicable field can carry out various modifications and combinations within the technical idea of the present invention. For example, although an npn-type InP/GaAsSb HBT on a SiC heat dissipation substrate that is promising in terms of realizing a very high speed integrated circuit is described in detail in the above embodiments, a similar effect is also achieved with other HBTs, such as an HBT formed on an InP substrate.

### REFERENCE SIGNS LIST

101 Heat dissipation substrate
102 Collector heat dissipation pad
103 Emitter heat dissipation pad
104 Base heat dissipation pad
105 Collector layer
106 Base layer
107 Emitter layer
108 Emitter cap layer
109 Emitter electrode
110 Base electrode
111 Emitter post electrode
112 Base post electrode
113 Insulation film
114 Emitter wiring
115 Base wiring
116 Collector wiring
117 Emitter heat dissipation via
118 Collector post electrode
119 Base heat dissipation via
120 Wiring formation layer.

1.-5. (canceled)

6. A device comprising:
a heat dissipation substrate that is insulating and has a higher thermal conductivity than InP;
a collector heat dissipation pad, an emitter heat dissipation pad, and a base heat dissipation pad, wherein the collector heat dissipation pad, the emitter heat dissipation pad, and the base heat dissipation pad are each metallic and in contact with an upper surface of the heat dissipation substrate, and wherein the collector heat dissipation pad, the emitter heat dissipation pad, and the base heat dissipation pad are insulated and separated from each other;
a collector layer on the collector heat dissipation pad, wherein the collector layer comprises a first compound semiconductor;
a base layer on the collector layer, wherein the base layer comprises a second compound semiconductor;
an emitter layer in contact with an upper surface of the base layer, wherein the emitter layer comprises a third compound semiconductor different from the second compound semiconductor;
an emitter cap layer on the emitter layer, wherein the emitter cap layer comprises a fourth compound semiconductor;
an emitter electrode on the emitter cap layer;
a base electrode on the base layer around the emitter layer;
an metallic emitter wiring in a wiring formation layer above the emitter cap layer, wherein the metallic emitter wiring is electrically connected to the emitter electrode;
a metallic base wiring in the wiring formation layer, wherein the metallic base wiring is electrically connected to the base electrode;
an metallic emitter heat dissipation via electrically connecting the metallic emitter wiring to the emitter heat dissipation pad; and
a metallic base heat dissipation via connecting the metallic base wiring to the base heat dissipation pad.

7. The device according to claim 6, further comprising:
a metallic collector wiring in the wiring formation layer, wherein the metallic collector wiring is electrically connected to the collector heat dissipation pad; and
a metallic collector post electrode connecting the metallic collector wiring to the collector heat dissipation pad.

8. The device according to claim 6, further comprising:
a metallic emitter post electrode connecting the metallic emitter wiring to the emitter electrode; and
a metallic base post electrode connecting the metallic base wiring to the base electrode.

9. The device according to claim 6, further comprising:
an insulation film on the heat dissipation substrate to cover an element portion, wherein the element portion comprises the collector layer, the base layer, the emitter layer, the emitter cap layer, the emitter electrode, and the base electrode, wherein the insulation film further covers the collector heat dissipation pad, the emitter heat dissipation pad, and the base heat dissipation pad, wherein the metallic emitter heat dissipation via passes through the insulation film over the emitter electrode, and wherein the metallic base heat dissipation via passes through the insulation film over the base electrode.

10. A manufacturing method for a bipolar transistor, comprising:
forming a metal layer on a heat dissipation substrate, wherein the heat dissipation substrate is insulating and has a higher thermal conductivity than InP;
forming an element portion on the metal layer, wherein the element portion comprises:
a collector layer comprising a first compound semiconductor;
a base layer on the collector layer, wherein the base layer comprises a second compound semiconductor;
an emitter layer in contact with an upper surface of the base layer, wherein the emitter layer comprises a third compound semiconductor that is different from the second compound semiconductor;
an emitter cap layer on the emitter layer, wherein the emitter cap layer comprises a fourth compound semiconductor;
an emitter electrode on the emitter cap layer; and
a base electrode that is on the base layer around the emitter layer;
forming, by patterning the metal layer, a collector heat dissipation pad, an emitter heat dissipation pad, and a base heat dissipation pad, wherein the collector heat dissipation pad, the emitter heat dissipation pad, and the base heat dissipation pad are each in contact with an upper surface of the heat dissipation substrate, and wherein the collector heat dissipation pad, the emitter heat dissipation pad, and the base heat dissipation pad are insulated and separated from each other;
contemporaneously forming an emitter heat dissipation via in contact with an upper surface of the emitter heat dissipation pad, a base heat dissipation via in contact with an upper surface of the base heat dissipation pad, a collector post electrode in contact with an upper surface of the collector heat dissipation pad, an emitter post electrode in contact with an upper surface of the emitter electrode, and a base post electrode in contact with an upper surface of the base electrode;
forming an insulation film on the heat dissipation substrate, the insulation film covering the element portion, the collector heat dissipation pad, the emitter heat dissipation pad, the base heat dissipation pad, the emitter heat dissipation via, the base heat dissipation via, the collector post electrode, the emitter post electrode, and the base post electrode; and
forming, in a wiring formation layer on the insulation film, an emitter wiring connected to the emitter post electrode by the emitter heat dissipation via.

11. The manufacturing method of claim 10, wherein the emitter heat dissipation via, the base heat dissipation via, the collector post electrode, the emitter post electrode, and the base post electrode are each made of a metal.

12. The manufacturing method of claim 10 further comprising forming, in the wiring formation layer, a base wiring connected to the base post electrode by the base heat dissipation via.

13. The manufacturing method of claim 12 further comprising forming, in the wiring formation layer, a collector wiring connected to the collector post electrode.

14. The manufacturing method of claim 13, wherein the emitter wiring, the base wiring, and the collector wiring are each made of a metal.

15. The manufacturing method of claim 13, wherein the emitter wiring, the base wiring, and the collector wiring are formed contemporaneously.

16. The manufacturing method of claim 13, wherein the emitter wiring, the base wiring, and the collector wiring each extend through the insulating film.

17. A device comprising:
an insulating substrate;
a collector heat dissipation pad, an emitter heat dissipation pad, and a base heat dissipation pad, wherein the collector heat dissipation pad, the emitter heat dissipation pad, and the base heat dissipation pad are each metallic and in contact with an upper surface of the insulating substrate, and wherein the collector heat dissipation pad, the emitter heat dissipation pad, and the base heat dissipation pad are insulated and separated from each other;
a collector layer on the collector heat dissipation pad;
a base layer on the collector layer;
an emitter layer in contact with an upper surface of the base layer;
an emitter cap layer on the emitter layer;
an emitter electrode on the emitter cap layer;
a base electrode on the base layer around the emitter layer;
an metallic emitter wiring electrically connected to the emitter electrode; and
an metallic emitter heat dissipation via connecting the metallic emitter wiring to the emitter heat dissipation pad.

18. The device according to claim 17, wherein the insulating substrate has a higher thermal conductivity than InP.

19. The device according to claim 17 further comprising:
a metallic base wiring electrically connected to the base electrode; and
a metallic base heat dissipation via connecting the metallic base wiring to the base heat dissipation pad.

20. The device according to claim 19, wherein the metallic base wiring is in a same wiring layer as the metallic emitter wiring.

21. The device according to claim 17 further comprising:
a metallic collector wiring electrically connected to the collector heat dissipation pad; and
a metallic collector post electrode connecting the metallic collector wiring to the collector heat dissipation pad.

22. The device according to claim 21, wherein the metallic collector wiring is in a same wiring layer as the metallic emitter wiring.

23. The device according to claim 17, wherein the collector layer, the base layer, the emitter layer, and the emitter cap layer each comprise a compound semiconductor.

24. The device according to claim 23, wherein the emitter layer comprises a different compound semiconductor than the base layer.
